(19) United States
(12) Patent Application Publication
(10) Pub. No.: US 2026/0268982 A1
(43) Pub. Date: Sep. 10, 2026

(54) CONCURRENCY CONTROL FOR REMOTE DISAGGREGATED MEMORY ARCHITECTURE

(71) Applicant: Hewlett Packard Enterprise Development LP, Spring, TX (US)

(72) Inventors: Sriram Ravishankar, Bangalore (IN); Gautham Bhat Kumbla, Bangalore (IN); Amitha Chandrachari, Bangalore (IN); Chinmay Ghosh, Bangalore (IN); Sharad Singhal, Belmont, CA (US)

(21) Appl. No.: 19/231,693

(22) Filed: Jun. 9, 2025

(30) Foreign Application Priority Data
Mar. 5, 2025 (IN) 202511019527

(51) Int. Cl. G11C 16/10

(52) U.S. Cl. CPC G11C 16/105

(57) ABSTRACT

Systems, methods, and devices for using distributed write records to maintain concurrency for remote data. A client device prepares to update remote data stored in a memory server that is exposed to the client device for remote memory access. Preparing to update the remote data includes allocating a region of the local memory to update the remote data and, in response to the allocation, storing a write record to the region. The write stores the update data in a data field and a location in one or more location fields. The location denotes where the update data of the write record is to be written. Furthermore, the client device, in response to storing the write record, flags the remote data as having a pending update at the location by updating metadata of the remote data.

### BACKGROUND

Computing devices, such as desktop computers or servers, may be deployed using a disaggregated memory architecture with memory servers (e.g., cloud platforms).

### BRIEF DESCRIPTION OF THE DRAWINGS

Features, aspects, and advantages of the present disclosure will become better understood when the following detailed description is read with reference to the accompanying drawings in which like characters represent like parts throughout the drawings, wherein:

FIG. 1 is a block diagram illustrating a computing system that uses distributed write records to maintain concurrency control for a remote disaggregated memory architecture using memory concurrency control (MCC) using processor(s) of one or more client devices, in accordance with aspects of the present disclosure;

FIG. 2 is a sequence diagram of a memory write using distributed storage, such as the memory servers and processor(s) of FIG. 1, in accordance with aspects of the present disclosure;

FIG. 3 is a block diagram of an implementation of metadata that may be stored in a memory server, such as the memory servers of FIG. 1, in accordance with aspects of the present disclosure;

FIG. 4 is a block diagram of an implementation of a write record that may be stored in a local memory of client devices, in accordance with aspects of the present disclosure;

FIG. 5 is a flow diagram of a process that may be used by one or more processors in writing to remote data in a memory server using locally stored write records, in accordance with aspects of the present disclosure;

FIG. 6 is a flow diagram of a computer-readable medium using instructions to implement a process related to writing to remote data, in accordance with aspects of the present disclosure;

FIG. 7 is a flow diagram of a process that may be used by one or more processors in reading remote data in a memory server that has distributed written data using locally stored write records at different remote devices, in accordance with aspects of the present disclosure;

FIG. 8 is a flow diagram of a computer-readable medium, that when executed, causes processor(s) to read remote data in a memory server that has distributed written data using locally stored write records at different remote devices, in accordance with aspects of the present disclosure;

FIG. 9 a flow chart of a process that may be implemented by a memory server, to merge remote write records with local data, in accordance with aspects of the present disclosure; and

FIG. 10 is a flow diagram of a computer-readable medium that includes instructions, that when executed by processor(s) of a memory serve merges remote write records with local data, in accordance with aspects of the present disclosure.

### DETAILED DESCRIPTION

The present disclosure relates generally to memory access in a disaggregated memory architecture (e.g., cloud platforms). Memory access time is often one of the controlling factors in how quickly data can be processed even in disaggregated memory. One method of limiting access time to increase processing using disaggregated memory is to use one-sided remote memory access (RMA). Specifically, one-sided RMA is becoming increasingly popular to access data from remote hosts because it has a low access time. For instance, memory may be attached in a fabric to provide access to disaggregated memory over RMA.

Access over RMA provides access with low access time but imposes inherent challenges while handling concurrent access. For example, when multiple clients try to update the same data over the network, RMA can be problematic. Typically, to address concurrency, an in-place update (i.e., lock-based architecture) using RMA uses locks which may be counterproductive as the locks impact the performance and other maintenance issues. As such, the use of such locks at least partially removes one main benefit, low access time, of using RMA. A lock-based architecture also results in multiple roundtrips over the network thereby increasing network data transfers per memory change and allows only one write to happen at a time where other clients wait to acquire the lock before writing. In alternative to the lock-based architecture, a pure log-based update uses more memory on the node (e.g., memory server) that is exposing the data to RMA as all updates are to be logged. However, log-based updating demands the node to allocate a large amount of memory to such logs.

To provide coherency control while maintaining low access time without logging all writes on the memory server, a linked-list-based scheme may be used providing clear benefits over pure log-based and lock-based architectures. The linked list enables multiple updates to a single data item to occur at least partially concurrently across multiple client nodes by linking to the changes in a distributed chain of entries in a linked list from the data item using metadata in the memory server. In the linked list, each client node keeps its changes in local memory in a respective write record. The metadata points to a first write record in a first client node that is first in the linked list that each successively points to another write record.

The order of the linked list is in order of writes made so that the data record has the oldest data and points to the next oldest data and so on. This linked-list-based architecture enables the updates to be maintained in a distributed manner through the client nodes attempting to write. This linked-list-based scheme enables clients to coherently write to the same data item without blocking any client while updating a record concurrently. In some implementations, the updates to linked the linked list may be performed using atomic operations (e.g., using a compare_and_swap instruction). This atomic methodology ensures that the linked list is consistent through concurrent updates.

This distributed linked list may be merged into the data item of the memory server at any time while maintaining the distributed linked list. For instance, the memory servers may merge all of the records into its own memory (i.e., remote memory) when a read is completed or may use a counter to perform merges periodically using a background process. This linked list implementation of concurrency may limit a number of round trips when each client uses local data to store a write record. Furthermore, this distributed implementation keeps from relying on consuming a large amount of resources of the memory server to track such writes.

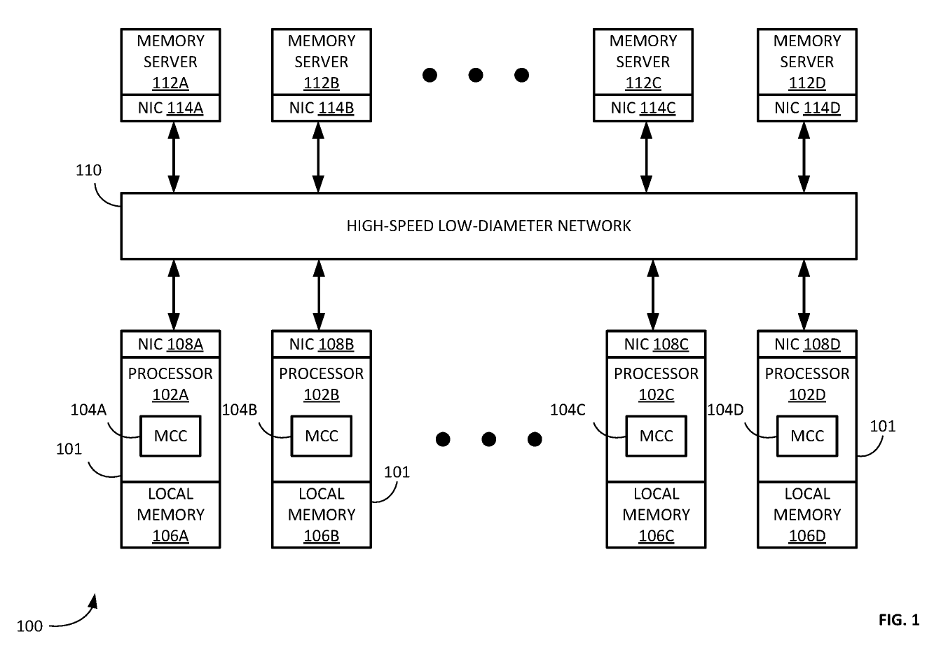

FIG. 1 is a diagram, illustrating a computing system 100 that has client devices 101 with one or more processors 102, individually referred to as processors 102A, 102B, 102C, and 102D. Although the illustrated implementation of the computing system 100 includes four processors, the computing system 100 may include any suitable number of processors 102, such as 1, 2, 3, 4, 5, 10s, 100s, or more processors. The one or more processors 102 may be one or more processing resources, such as a central processing unit (CPU), a graphics processing unit (GPU), implemented using a field programmable gate array (FPGA), or a combination thereof. The one or more processors 102 may implement various stored programs, such as respective memory concurrency controls (MCC) 104A, 104B, 104C, and 104D (collectively referred to as MCC 104). Accordingly, the computing system 100 may include any suitable computing devices that may utilize one or more processors 102, such as servers, desktop computers, laptop computers, tablet computers, cellular devices, wearable devices, and/or other computing devices. In some implementations, the MCC 104 may be at least partially implemented using respective processors 102 and/or using a memory controller.

The programs or instructions executed by the one or more processors 102 may be stored in any suitable article of manufacture that includes one or more non-transitory and computer-readable media at least collectively storing the instructions or routines. For instance, the instructions may be stored in a memory 106 (individually referred to as 106A, 106B, 106C, and 106D) corresponding to a respective processor 102. For instance, a first computing device (e.g., a computer) may include the processor 102A and the local memory 106A, a second computing device may include the processor 102B and the local memory 106B, a third computing device may include the processor 102C and the local memory 106C, and a fourth computing device may include the processor 102D and the local memory 106D. Although each processor 102 is shown to correspond to a single memory 106, at least some processors 102 may be part of computing devices that include more than one memory 106. Moreover, in some implementations, such computing devices may include more than one processor 102. In other words, the number of memories 106 and the processors 102 may be the same or may be different in the computing system 100.

The memory 106 may include any suitable articles of manufacture suitable for storing data and/or executable instructions that may be executed by the one or more processors 102. The memory 106may include any suitable memory devices, such as random-access memory (RAM), including but not limited to, double data rate type 5 (DDR5) synchronous dynamic random-access memory (SDRAM), double data rate type 4 (DDR4) SDRAM, low-power double data rate (LPDDR) SDRAM, another suitable type of memory device, or any combination thereof. The memory 106 may include one or more different memory devices. Additionally or alternatively, the memory 106 may include a storage device, such as a Non-Volatile Memory Express (NVMe) device, a hard disk drive (HDD), a solid-state drive (SSD), an optical drive, another type of storage device, flash memory, read-only memory (ROM), or any combination thereof.

To facilitate control of the memory 106 and/or exchange of data between the one or more processors 102 and the memory 106, the computing system 100 may include a memory controller (e.g., as part of the processor(s) 102). The memory controller may be a hardware and/or software component that connects one or more diverse types of memory in the memory 106 to the one or more processors 102 (e.g., via a processor bus of the one or more processors 102). The memory controller may be part of the one or more processors 102 and/or may be implemented on a separate chip mounted on a baseboard of the computing system 100. The MCC 104 may be at least partially implemented in the memory controller. During a power up of the computing system 100, the memory controller configures and enables use of specific memory devices of the memory 106. Additionally, the memory controller may manage various functions, such as error correction, memory refresh operations, and power management of the memory 106.

The computing system 100 may further include one or more network interface controllers (NICs) 108, individually referred to as NICs 108A, 108B, 108C, and 108D. The NICs 108 may be hardware components or combinations of hardware and software that connects the processors 102 to one or more networks, such as a high-speed low-diameter network 110. The NICs 108 provide a connection for the respective processors 102 and their computing devices to interconnect via the high-speed low-diameter network 110.

The high-speed low-diameter network 110 may be a wired and/or wireless connection of electronic devices, such as switches, routers, access points, and/or other electronic devices to enable interconnection of electronic devices. For instance, the high-speed low-diameter network 110 may connect the computing devices and their processors 102 together using Ethernet, powerline adapters, IEEE 802.15 wireless connections, and/or any other suitable interconnection types.

Through the high-speed low-diameter network 110, the computing devices and their processors 102 connect to one or more memory servers 112 (individually referred to as memory servers 112A, 112B, 112C, and 114D). Although the illustrated implementation shows four memory servers 112, some implementations of the computing system 100 may include any suitable number of memory servers 112, such as 1, 2, 3, 4, 5, tens, hundreds, or thousands of memory servers 112. Furthermore, in some implementations, the memory servers 112 may be compute nodes that include memory and processing (e.g., processors 102).

Each memory server 112 may be and/or include network-connected memories. These memories may include any suitable memory devices, such as random-access memory (RAM), including but not limited to, double data rate type 5 (DDR5) synchronous dynamic random-access memory (SDRAM), double data rate type 4 (DDR4) SDRAM, low-power double data rate (LPDDR) SDRAM, another suitable type of volatile or non-volatile memory, or any combination thereof. The memory servers 112 may include one or more different memory devices. Additionally or alternatively, the memory servers 112 may include a storage device, such as a Non-Volatile Memory Express (NVMe) device, a hard disk drive (HDD), a solid-state drive (SSD), an optical drive, another type of storage device, flash memory, read-only memory (ROM), or any combination thereof.

The memory servers 112 may connect to the high-speed low-diameter network 110. For instance, the memory servers 112 may include respective network interface controllers (NICs) 114, individually referred to as 114A, 114B, 114C, and 114D. The network interface controllers 114 may be hardware components or combinations of hardware and software that connects the memory servers 112 to one or more networks, such as a high-speed low-diameter network 110. The NICs 114 provide a connection for the memory servers 112 to interconnect to the processors 102 and/or each other via the high-speed low-diameter network 110.

The memory servers 112 may expose at least some of their own memories to the processors 102 as remote memories through the high-speed low-diameter network 110 and the NICs 108 and 114. For instance, in some implementations, the memory servers 112 may expose at least a portion of their local memory to the processors 102 as part of remote direct memory access (RDMA) capabilities of the NICs 108 and/or 114. This exposure enables the processors 102 to directly transfer data to and/or from the memory servers 112 without intervention of any processors of the memory servers 112. Exposing the local memory may include installing and/or using RDMA drivers in the NICs 108 and/or 114, configuring the NICs 108 and/or 114 to support one or more RDMA protocols, the processor 102 using application libraries to interact with the NICs 108 and/or 114, and the like. For instance, RDMA protocols may include an RDMA over Converged Ethernet (RoCE) protocol, IETF’s iWARP RDMA over IP (iWARP) protocol, and the like. As previously noted, the processors 102 use respective MCC 104 to manage concurrent memory writes/reads to the memory servers 112 using a remote memory management mechanism, such as RDMA.

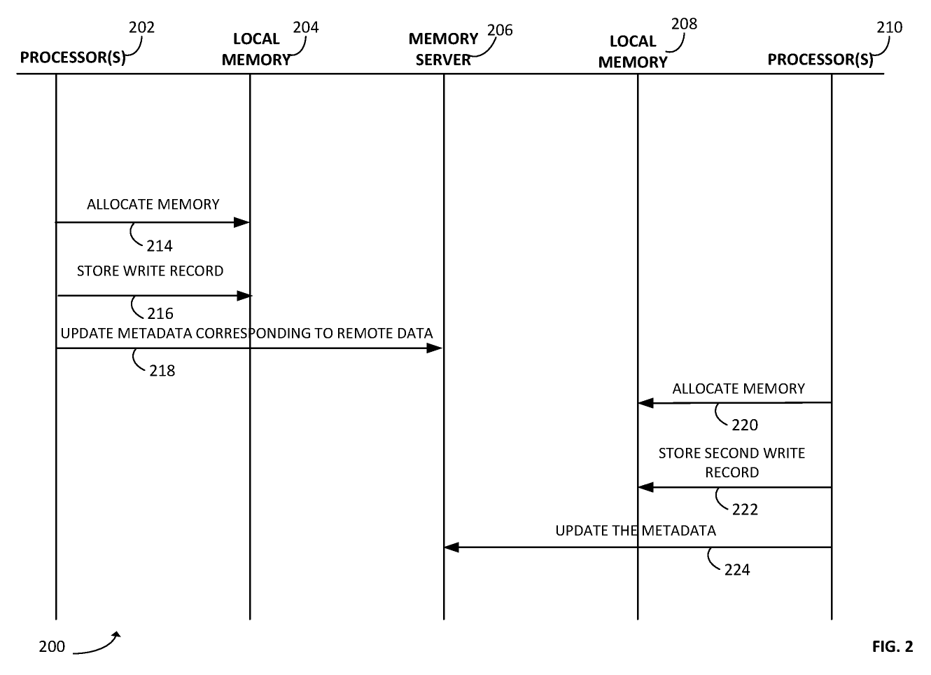

FIG. 2 is a sequence diagram 200 of a memory write using distributed storage, such as the memory servers 112. For instance, the memory write may include a remote direct memory access (RDMA) by processors, such as the processors 102, by executing instructions to perform the memory write using instructions that are part of a memory concurrency control (MCC), such as the MCC 104.

The sequence diagram 200 illustrates one or more processors 202, a local memory 204 corresponding to the processor(s) 202, a memory server 206, a local memory 208, and one or more processors 210 corresponding to the local memory 208. Although the illustrated implementation of the distributed memory write includes two processors with respective local memories, a distributed write operation may be distributed where more or fewer processors participate in the distributed write. One example of the processors 202 and/or 210 may be the processor(s) 102of the client devices 101. Likewise, one example of the local memories 204 and 208 may be the local memory 106of the client devices 101. Furthermore, one example of the memory server 206 may be one of the memory servers 112.

The processor(s) 202 and/or 210 may be one or more processing resources, such as a central processing unit (CPU), a graphics processing unit (GPU), implemented using a field programmable gate array (FPGA), or a combination thereof. The processor(s) 202 and/or 210 may implement various stored programs, such as respective memory concurrency controls (MCC), such as the MCC. Accordingly, the processor(s) 202 and/or 210 may be part of any suitable computing devices that may utilize the processor(s) 202 and/or 210, such as client devices, servers, desktop computers, laptop computers, tablet computers, cellular devices, wearable devices, and/or other computing devices. In some implementations, the MCC may be at least partially implemented using respective processor(s) 202 and/or 210.

The programs or instructions executed by the processor(s) 202 and/or 210 may be stored in any suitable article of manufacture that includes one or more non-transitory and computer-readable media at least collectively storing the instructions or routines. For instance, the instructions may be stored in the local memories 204 and/or 208. For instance, a first computing device (e.g., a computer) may include the processor(s) 202 and the local memory 204 while a second computing device may include the processor(s) 210 and the local memory 208. Although each of the processor(s) 202 and 210 is shown to correspond to a single local memory 204 and 204, at least some implementations of the processor(s) 202 and/or 210 may be part of respective computing devices that include more than one local memory. Moreover, in some implementations, such computing devices may include more than one processor 102. In other words, the number of memories and processors may be the same or may be different in the respective computing devices.

The local memories 204 and 208 may include any suitable articles of manufacture suitable for storing data and/or executable instructions that may be executed by respective processor(s) 202 and 210. The local memories 204 and 208 may include any suitable memory devices, such as random-access memory (RAM), including but not limited to, double data rate type 5 (DDR5) synchronous dynamic random-access memory (SDRAM), double data rate type 4 (DDR4) SDRAM, low-power double data rate (LPDDR) SDRAM, another suitable type of memory device, or any combination thereof. The local memories 204 and 208 may include one or more different memory devices. Additionally or alternatively, the memory 106 may include a storage device, such as a Non-Volatile Memory Express (NVMe) device, a hard disk drive (HDD), a solid-state drive (SSD), an optical drive, another type of storage device, flash memory, read-only memory (ROM), or any combination thereof. In some implementations, the local memories 204 and 208 may be the same types of memory or may be different types of memory.

The memory server 206 may be part of a group of one or more memory servers. Additionally, the memory server 206 may include one or more memories. These memories may include any suitable memory devices, such as random-access memory (RAM), including but not limited to, double data rate type 5 (DDR5) synchronous dynamic random-access memory (SDRAM), double data rate type 4 (DDR4) SDRAM, low-power double data rate (LPDDR) SDRAM, another suitable type of volatile or non-volatile memory, or any combination thereof. The memory server 206 may include one or more different memory device types. Additionally or alternatively, the memory server 206 may include a storage device, such as a Non-Volatile Memory Express (NVMe) device, a hard disk drive (HDD), a solid-state drive (SSD), an optical drive, another type of storage device, flash memory, read-only memory (ROM), or any combination thereof.

The memory server 206 may connect to processor(s) 202 and 210 via a one or more networks, such as the high-speed low-diameter network 110. Such connections may be implemented via respective network interface controllers (NICs), such as the NICs 108 and/or 114. The NICs may be hardware components or combinations of hardware and software that connects the memory server 206 to the one or more networks. The NICs provide a connection for the memory server 206 to interconnect to the processor(s) 202 and 210 via the one or more networks.

The memory server 206 exposes at least some of its local memory to the processors 202 and 210 as remote memory through the one or more networks and respective NICs. For instance, in some implementations, the memory server 206 may expose at least a portion of its local memory to the processors 202 and 210 as part of remote direct memory access (RDMA) capabilities of the NICs. This exposure enables the processor(s) 202 and/or 210 to directly transfer data to and/or from the memory server 206 without intervention of any processors of the memory server 206. Exposing the memory that is remote from other devices (e.g., client devices) and local to the memory server 206 may include installing and/or using RDMA drivers in the NICs of the processor(s) 202 and/or 210 or of the memory server 206, configuring the NICs to support one or more RDMA protocols, the processor(s) 202 and/or 210 using application libraries to interact with the NICs, and the like. For instance, RDMA protocols may include an RoCE protocol, an iWARP protocol, and/or the like. As previously noted, the processor(s) 202 and/or 210 use respective MCC to manage concurrent memory writes/reads to the memory server 206 using a remote memory management mechanism, such as RDMA.

In preparation to update remote data of the memory server 206, the processor(s) 202 allocate memory (214) of the local memory 204. This allocation may be in response to an application running on the processor(s) 202 that has a result (e.g., a computation) that calls for an update to remote data stored in the memory server 206. In other words, in some implementations, the allocation of memory for a remote write may be made after there is a reason to update remote data. Alternatively, a portion of the local memory 204 may be pre-allocated without a current demand to update remote data as a standing allocation that is available for remote writes. For instance, the allocation may be performed upon boot up of the computing device that includes the processor(s) 202 and the local memory 204 and/or when the MCC is executed by the processor(s) 202.

Regardless of when the allocation is made, the processor(s) 202 store a write record (216) in the allocated portion of the local memory 204 with data to be updated to remote data of the memory server 206. Storing may include generating the write record before or during storage. The write record is stored in the local memory 204 and may correspond to metadata that is stored in the memory server 206. The write record and the metadata are used to track pending write operations to the remote data.

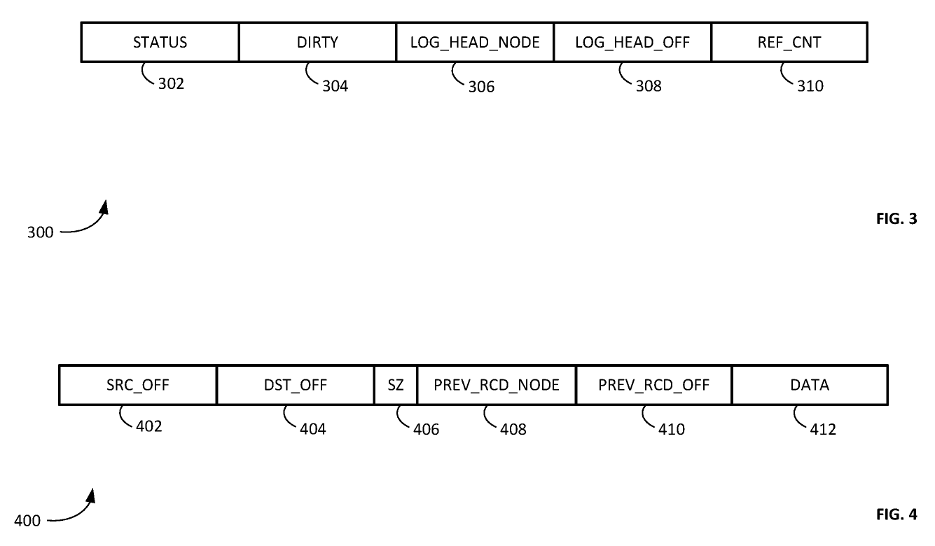

FIG. 3 is a block diagram of an implementation of metadata 300 that may be stored in a memory server, such as the memory servers 112and/or 206. The metadata 300 along with one or more write records are used to track pending writes to memory (e.g., remote data) of the memory server(s) (e.g., memory server(s) 112) in a manner that maintains coherency without overly taxing one or more networks through which the remote data may be written and/or read.

The metadata 300 includes a status field 302. The status field 302 tracks whether the remote data is stable and not involved in an ongoing merge of pending writes. To this point, the status field 302 includes a value that indicates whether the remote data is stable. For instance, in some implementations, as long as a current merge of pending writes is being performed or soon to be performed, the status field 302 may store a value (e.g., 0) indicating that the data is stable. Otherwise, the status field 302 may store a value (e.g., 1) indicating that the data is not stable.

The metadata 300 also includes a dirty field 304. The dirty field 304 tracks whether a pending write exists for the remote data. To this point, the dirty field 304 includes a value that indicated whether the remote data is dirty. The data is dirty when it has a pending write that has not been merged yet. If a pending write exists, the dirty field 304 stores a first value (e.g., 0) when there are no pending unmerged writes but stores a second value (e.g., 1) when there is a pending unmerged write.

When there is a pending write, the metadata 300 points to a write record in a log_head_node field 306. The log_head_node field 306 indicates an address of a computing device that stores a latest/most recent pending write record. In other words, the log_head_node field 306 indicates the most recent computing device to attempt to modify the remote data from its current state with a pending write and corresponding write record. This node acts as a head of a log of write records as it would point to a previous/next most recent write record and so forward. When there is no pending write, the log_head_node field 306 may carry a specific value (e.g., null or zero). Alternatively, the log_head_node field 306 may be ignored completely when the dirty field 304 indicates that there are no pending writes.

In addition to the log_head_node field 306, the metadata 300 may include a log_head_off field 308 that stores a memory offset to the write record in the memory of the first computing device. In other words, the log_head_node field 306 points to the computing device storing a write record, and the log_head_off field 308 points to a location within the computing device where the write record is stored. Thus, when the data is flagged as dirty, the metadata 300 tracks both the device and the location within the device where the write record is stored.

The metadata 300 may also include a reference count field 310 that is used to track a number of pending reads to the remote data. The reference count field 310 may be incremented for each pending read and decremented after the read has been completed. When the reference count field 310 stores a value indicating that at least one read is pending, any updates of the remote data via a merge of the remote data with write record data may be delayed until the value of the reference count field 310 indicates that no read operations are pending.

In some implementations, the metadata 300 may be stored along with (e.g., adjacent to) the remote data. Indeed, in some implementations, the metadata 300 may be in headers of allocated memory with a data item that stores the remote data in the memory server.

FIG. 4 is a block diagram of an implementation of a write record 400 that may be stored in a local memory, such as the memory 106 or the local memories 204 and/or 208. One or more write records 400 along with corresponding metadata, such as the metadata 300, are used to track pending writes to memory (e.g., remote data) of the memory server in a manner that maintains coherency without overly taxing one or more networks through which the remote data may be written and/or read. The write record(s) 400 along with the corresponding metadata are configured to track where each write record stands in time in relation to other pending writes to the remote data. This linked list in the multiple local memories enables a distributed memory architecture that maintains coherency without the delays and/or resource consumption of lock-based or log-based schemes.

The write record 400 includes a source offset field 402 that tracks a location within a source (e.g., registered buffer) where the modified data exists. In other words, the source offset field 402 indicates where in the local memory the modified data exists.

The write record 400 also includes a destination offset field 404 that tracks a location within a destination (e.g., remote data in the memory server) where the modified data is to go. In other words, the destination offset field 404 indicates a precise location where the update is to be placed in the remote data.

The write record 400 also includes a size field 406 that tracks a size of the update data of the write record. In other words, by indicating the source location and the destination location along with the size, the MCC may elucidate exactly which bits of the remote data are to be replaced with the modified update data of the write record.

The write record 400 may also point to a previously received record that corresponds to the next most recent write. Specifically, the write record 400 may include a prev_rcd_node field 408 that tracks a location of a computing device that stores the next most recent write record. In other words, the prev_rcd_node field 408 stores a value that indicates an address (e.g., IP address) of the computing device where the next most recent write record is stored.

The write record 400 may also track where the next most recent write record in the other computing device. Specifically, the write record 400 may include a prev_rcd_off field 410 that tracks where the next most recent write record is located in a memory of the computing device. In other words, the prev_rcd_off field 410 stores a value that is an indication of an offset to the next most recent write record in the memory of the computing device storing the next most recent write record. Finally, the write record 400 may include a data field 412 that corresponds to the update to the remote data.

Returning to FIG. 2, in storing the write record, the processor(s) 202 may read the metadata for the remote data from the memory server 206 to determine whether the metadata indicates that there is a pending write with a write record located in another device connected to the memory server 206 via one or more networks. For instance, the processor(s) 202 may access the dirty field (e.g., dirty field 304) of the metadata that indicates whether there is another pending write. If there is a pending write, the processor(s) 202 may determine the location of a next most recent write record (e.g., via the log_head_node field 306 and the log_head_off field 308) and write that location to the write record. For instance, the write record may be encoded with the location (e.g., in the prev_rcd_node field 408 and the prev_rcd_off field 410). However, if there is no other pending write indicated in the metadata, storing the write record may include storing an indication (e.g., null or another predefined value) in a prev_rcd_node field (e.g., the prev_rcd_node field 408) that indicates that no other writes are pending and thus no other linked write records exist.

Once the write record is stored in local memory 204, the processor(s) 202 updates the metadata corresponding to the remote data (218). For instance, the processor(s) 202 may update the metadata to point to the newly stored write record as the new log head. Specifically, the update to the metadata may indicate the location of the device having the local memory 204 (e.g., log_head_node field 306) and a location within the device of the write record (e.g., log_head_off field 308). In some implementations, the storing of the write record along with writing the metadata may be an atomic operation that occurs as a single operation.

Before, during, and/or after storing of the write record by the processor(s) 202, the processor(s) 210 may prepare to update the remote data stored in the memory server 206 by allocating a region of memory (220) in the local memory 208. This allocation may be in response to an application running on the processor(s) 210 that has a result (e.g., a computation) that calls for an update to remote data stored in the memory server 206. In other words, in some implementations, the allocation of memory for a remote write may be made after there is a reason to update remote data. Alternatively, a portion of the local memory 208 may be pre-allocated without a current demand to update remote data as a standing allocation that is available for remote writes. For instance, the allocation may be performed upon boot up of the computing device that includes the processor(s) 210 and the local memory 208 and/or when the MCC is executed by the processor(s) 210.

The processor(s) 210 store a write record (222) in the allocated portion of the local memory 208 with data to be updated to remote data of the memory server 206. The write record is stored in the local memory 208 and may correspond to metadata that is stored in the memory server 206. The write record and the metadata are used to track pending write operations to the remote data.

In storing the write record, the processor(s) 210 may read the metadata for the remote data from the memory server 206 to determine whether the metadata indicates that there is a pending write with a write record located in another device connected to the memory server 206 via one or more networks. For instance, the processor(s) 210 may access the dirty field (e.g., dirty field 304) of the metadata that indicates that there is a pending write corresponding to the write record in the local memory 204. The processor(s) 210 may receive the location of the local memory 204 as the next most recent write record (e.g., via the log_head_node field 306 and the log_head_off field 308 of the metadata) and write that location to the write record. For instance, the processor(s) 210 may encode the write record with the location (e.g., in the prev_rcd_node field 408 and the prev_rcd_off field 410).

The processor(s) 210 also updates the metadata corresponding to the remote data (224). For instance, the processor(s) 210 may update the metadata to point to the newly stored write record as the new log head. Specifically, the update to the metadata may indicate the location of the device having the local memory 208 (e.g., log_head_node field 306) and a location within the local memory 208 of the write record (e.g., log_head_off field 308). As a result of the storing of the write record and the update of the metadata, the metadata points to the write record of the local memory 208 as the most recent pending write. The write record of the local memory 208, in turn, points to the write record of the local memory 204 as the next most recent pending write. Using such linked connections, the remote data may be accessed by multiple remote devices using remote mechanisms, such as RDMA, without compromising concurrency controls and without the delays and/or overhead that is inherent in applying a locking scheme or a memory server-based log scheme.

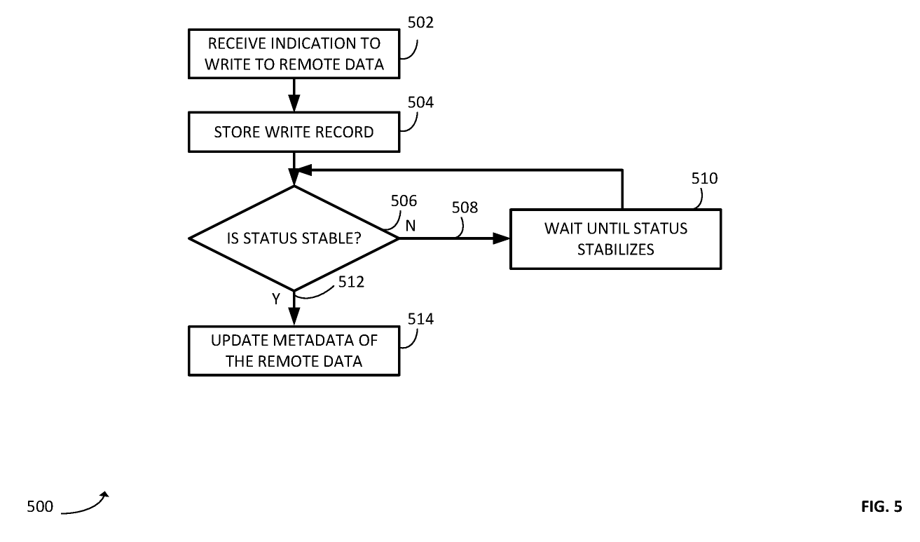

FIG. 5 is a flow diagram of a process 500 that may be used by one or more processors, such as the processor(s) 102, 202, and 210, in writing to remote data in a memory server (e.g., memory server(s) 112) using stored write records stored in local memory 106. The processor(s) receives an indication that it is to write to remote data (block 502). For instance, an application running on the processor performs a computation, a measurement, and/or other operation that changes what should be stored in the remote data.

The processor(s) then stores a write record in local memory (block 504). For instance, the processor(s) may store the update data in local memory (e.g., local memory 106) that stores the data and stores an indication of where the update data fits into the remote data, such as the src_off field 402 and/or the dst_off field 404.

As part of storing the write record and/or receiving the indication to write to the remote memory, the processor(s) (e.g., processor(s) 102) may derive information about the remote data including whether there are pending writes, whether there are pending reads, and whether the remote data is stable. The remote data is stable if it is not currently being merged with other write records. Such information may be encoded in metadata of the remote data. For instance, a status field, such as the status field 302, may indicate whether the remote data is stable or unstable. Likewise, a dirty bit/field, such as the dirty field 304, may indicate whether there are any pending writes, and a reference count, such as the ref_cnt field 310, may indicate whether there are any pending reads. If there are any pending writes as indicated by a most recent pending write in the metadata in respective one or more fields (e.g., the log_head_node 306 or the log_head_off 308), it may store such information in the write record for when the write record is inserted as the most recent pending write.

The processor(s) checks this information to determine how to proceed with the write. For instance, the processor(s) check this information to determine whether the status is stable for the remote data based on the status field 302 (block 506). If the status is not stable (508) due to an ongoing merge of one or more write records into the remote data, the processor(s) wait until the status stabilizes (block 510). For instance, the processor(s) may subscribe to notifications about the remote data and wait until receiving a notification from the memory server that the merge of the remote data has been completed. Alternatively, the processor(s) may wait a pre-determined period of time and/or may poll the memory server to acquire an updated status of the remote data at a later time.

If the processor(s) determine that the remote data is stable (512), the processor(s) may update the metadata of the remote data (block 514). Updating the metadata of the remote data includes writing an address of the computing device of the processor(s) to the metadata along with a location within the computing device. This change of the address and location by the processor(s) amounts to the processor(s) denoting that its data is to be written to remote data after any previous pending writes with corresponding write records.

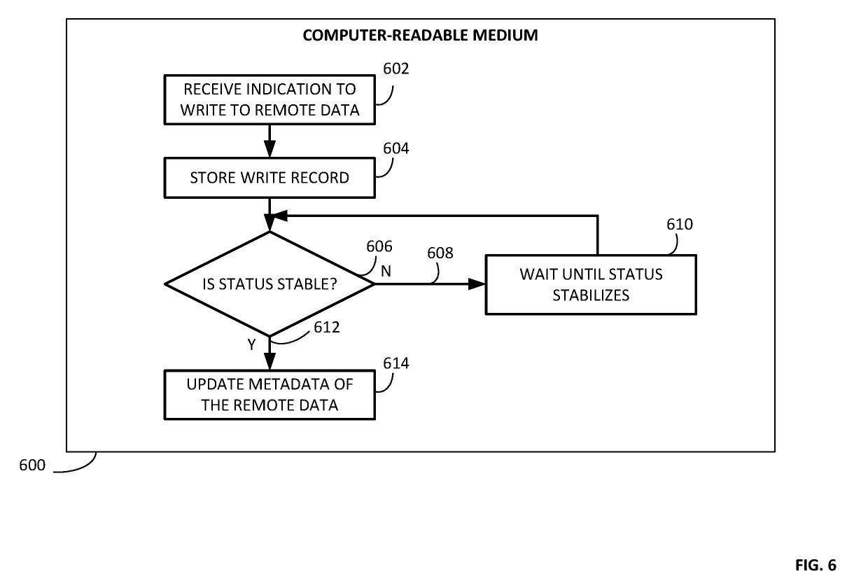

FIG. 6 is a flow diagram of a computer-readable medium 600 using instructions to implement a process related to writing to remote data. Instructions may be stored in memory, such as the memory 106, the local memory 204, and/or the local memory 208, that may be used by one or more processors, such as the processor(s) 102, 202, and 210, in writing to remote data in a memory server (e.g., memory server(s) 112) using write records stored in local memory, such as local memory 106. For instance, the instructions may be part of one or more applications running on the processor(s). For example, the applications may include a memory concurrency control (MCC), such as the MCC 104. The instructions, when executed, cause the processor(s) (e.g., processor(s) 102) to receive an indication that it is to write to remote data (block 602). For instance, an application running on the processor performs a computation, a measurement, and/or other operation that changes what should be stored in the remote data.

The instructions, when executed by the processor(s), cause the processor(s) to store a write record in local memory (block 604). For instance, the processor(s) may store the update data in local memory that stores the data and store an indication of where the update data fits into the remote data, such as the src_off field 402 and/or the dst_off field 404.

As part of storing the write record and/or receiving the indication to write to the remote data and based on the instructions, the processor(s) may derive information about the remote data including whether there are pending writes, whether there are pending reads, and whether the remote data is stable. The remote data is stable if it is not currently being merged with other write records. Such information may be encoded in metadata of the remote data. For instance, a status field, such as the status field 302, may indicate whether the remote data is stable or unstable. Likewise, a dirty bit/field, such as the dirty field 304, may indicate whether there are any pending writes, and a reference count, such as the ref_cnt field 310, may indicate whether there are any pending reads. If there are any pending writes as indicated by a most recent pending write in the metadata in respective one or more fields (e.g., the log_head_node 306 or the log_head_off 308), it may store such information in the write record for when the write record is inserted as the most recent pending write.

The instructions, when executed, cause the processor(s) to check this information to determine how to proceed with the write. For instance, based on the instructions, the processor(s) may check this information to determine whether the status is stable for the remote data (block 606). If the status is not stable (608) due to an ongoing merge of one or more write records into the remote data, the instructions, when executed, cause the processor(s) to wait until the status stabilizes (block 610). For instance, the processor(s) may subscribe to notifications about the remote data and wait until receiving a notification from the memory server that the merge of the remote data has been completed. Alternatively, the processor(s) may wait a pre-determined period of time and/or may poll the memory server to acquire an updated status of the remote data at a later time.

If the remote data is stable (612), the instructions, when executed, cause the processor(s) to determine whether there are any ongoing read(s) (block 614). The processor(s) may determine this information by evaluating a corresponding portion (e.g., ref_cnt field 310) of the metadata to determine whether any connected devices are remotely reading the remote data. For instance, if a reference count matches a value (e.g., greater than 0), there is at least one ongoing read occurring. If there is at least one ongoing read (616) due to an ongoing read of the remote data, the instructions cause the processor(s) to wait until the read(s) are (block 618). For instance, the processor(s) may subscribe to notifications about the remote data and wait until receiving a notification from the memory server that the read(s) of the remote data has been completed. Alternatively, the processor(s) may wait a pre-determined period of time and/or may poll the memory server to acquire an updated status of the read(s) of the remote data at a later time.

If no merges or reads of the remote data are ongoing (620), the instructions, when executed, cause the processor(s) to update the metadata of the remote data (block 624). Updating the metadata of the remote data includes writing an address of the computing device of the processor(s) to the metadata along with a location within the computing device. This change of the address and location by the processor(s) amounts to the processor(s) denoting that its data is to be written to remote data after any previous pending writes with corresponding write records.

In some implementations, the write record (e.g., in block 604) may be delayed until status and ongoing read(s) have been cleared. For instance, the write record may be stored after the block 620 but before and/or during updating the metadata. In some implementations, storing to the write record may be completed in two parts with the update data being stored before checking for stability and/or for read operation(s) and updating the write data and the metadata after checking for stability and/or for read operation(s).

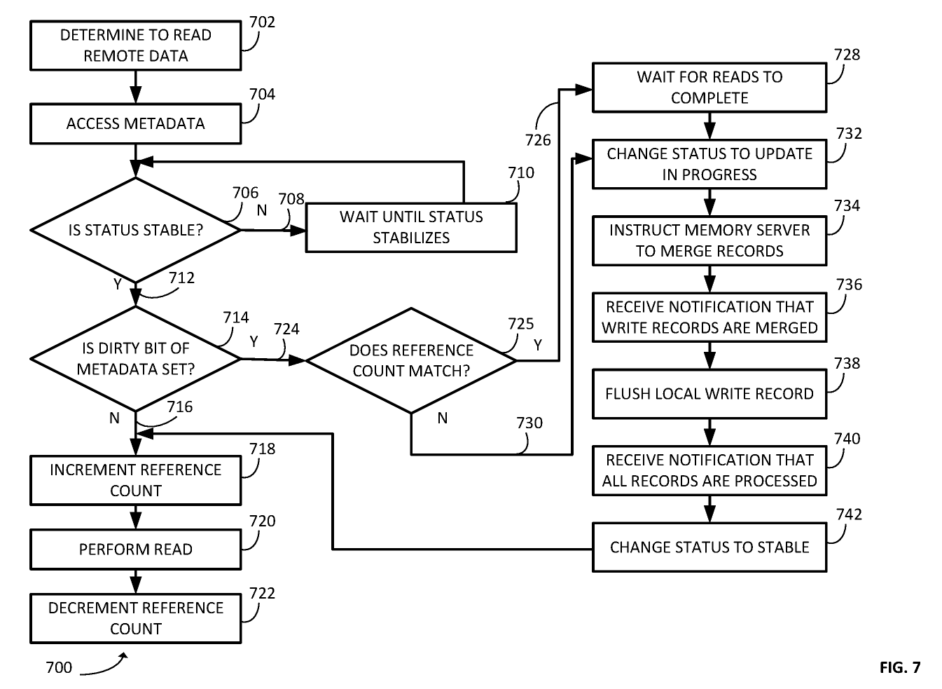

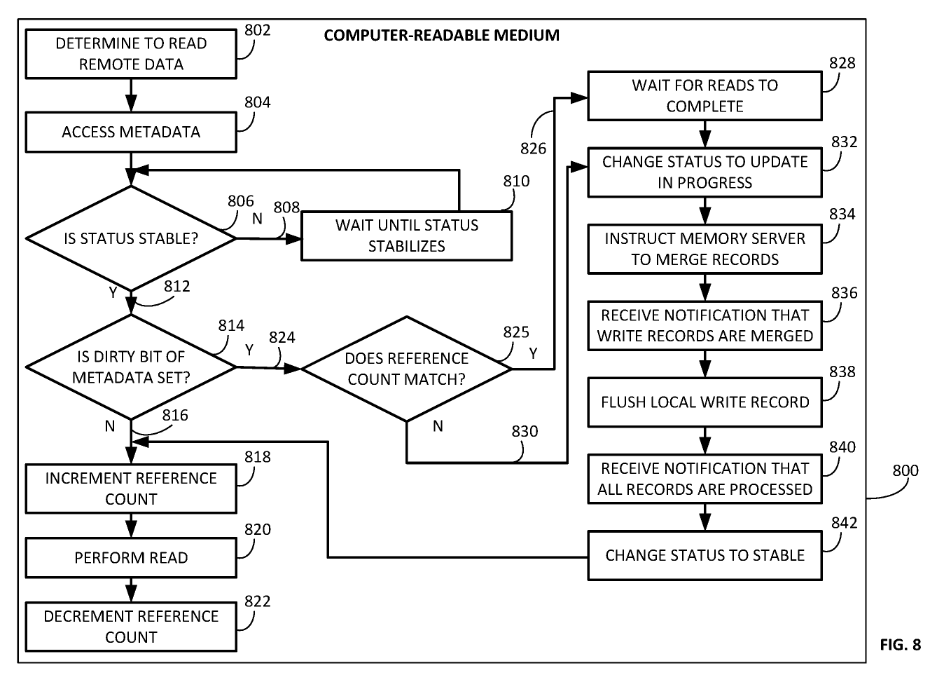

FIG. 7 is a flow diagram of a process 700 that may be used by one or more processors, such as the processor(s) 102, 202, and 210, in reading remote data in a memory server that has distributed written data using write records at local memories of different remote devices. For one example, the write records may be distributed among different local memories 106of different client devices 101. The processor(s) receives an indication that it is to read remote data (block 702). For instance, an application running on the processor(s) is to use such remote data for a computation, a measurement, and/or other operation that is based at least in part on the remote data.

The processor(s) then accesses metadata of the remote data (block 704). For instance, the processor(s) may remotely access (e.g., using RDMA) a register of the memory server storing the remote data. The metadata includes information about the remote data, such as whether the remote data is undergoing a merge of multiple writes (e.g., using the status field 302), whether the remote data is undergoing a read (e.g., using the ref_cnt field 310), whether the remote data has pending writes that are currently not being merged (e.g., using the dirty field 304, the log_head_node field 306, and/or the log_head_off field 308).

The processor(s) checks this information to determine how to proceed with the read. For instance, the processor(s) check this information to determine whether the status is stable for the remote data (block 706). If the status is not stable (708) due to an ongoing merge of one or more write records into the remote data as indicated in a status field of the metadata, the processor(s) may wait until the status stabilizes (block 710). For instance, the processor(s) may subscribe to notifications about the remote data and wait until receiving a notification from the memory server that the merge of the remote data has been completed. Alternatively, the processor(s) may wait a pre-determined period of time and/or may poll the memory server to acquire an updated status of the remote data at a later time.

If the processor(s) determine that the remote data is stable based on the metadata (712), the processor(s) may determine whether the remote data is dirty based on the dirty field 304 (block 714). The processor(s) may determine this information by evaluating a corresponding flag in a corresponding portion (e.g., dirty field 304) of the metadata to determine whether the remote data is dirty.

If the remote data is not dirty (716) without any pending reads or writes, the processor(s) increment a reference count (718). The reference count (e.g., the ref_cnt field 310) is a count of ongoing reads. Once the reference count has been incremented, the processor(s) may read the data from remote data (block 720). For instance, the processor(s) may use a remote access mechanism (e.g., RDMA) to read the remote data from the memory server. After completing the read, the processor(s) may decrement the reference count (block 722). In other words, the processor(s) may increment the reference count when a read is to happen or is happening and decrements the reference count after the read has been completed.

If the remote data is dirty (724), the processor(s) may determine whether the reference count matches a pre-defined value (block 725). For instance, the pre-defined value may be any value greater than zero, indicating that there is at least one outstanding read operation. The processor(s) may determine this information by evaluating a corresponding portion (e.g., ref_cnt field 310) of the metadata to determine whether any connected devices are remotely reading the remote data. For instance, if a reference count matches the value (e.g., greater than 0), there is at least one ongoing read occurring. If there is at least one ongoing or pending read (726) of the remote data, the processor(s) wait until the read(s) are completed (block 728). For instance, the processor(s) may subscribe to notifications about the remote data and wait until receiving a notification from the memory server that the read(s) of the remote data has been completed. Alternatively, the processor(s) may wait a pre-determined period of time and/or may poll the memory server to acquire an updated status of the read(s) of the remote data at a later time.

After the reads are completed (728) and/or upon determining that the reference count does not match a pre-determined value indicating of an outstanding read (730), the processor(s) may cause the write records to be merged together. In anticipation of such a merge, the processor(s) initiating the read changes the status in the metadata to an update-in-progress state rather than a stable state (block 732). In other words, the read invokes a merge that renders the data unstable until the merge is completed. The processor(s) may mark this remote data as unstable in anticipation of the merge.

After changing the status of the remote data to unstable, the processor(s) send a merge instruction to the memory server to merge the write records into the remote data (block 734). In some implementations, the merge instruction may be separate from the read request and/or may be included with or implied by the read request without a separate merge instruction. As is discussed below in reference to the memory server, the memory server merges the remote data with the write records in an oldest to most recent order to make sure that all updates are processed in order received.

As part of the merge and/or after merging the write records, the processor(s) (and any other devices with a write record) receive a notification that write records have been merged to the remote data (block 736). The notification may be a release notification that indicates that the write record is no longer pending and has been merged with the remote data. Accordingly, in response to the notification, the processor(s) flush the corresponding locally stored write record (block 738). For instance, the processor(s) may delete any locally stored write record upon notification that such write records have been processed. For example, the deletion may include formatting the region or freeing up the allocation for the write record.

Since the processor(s) initiated the merge, the processor(s) may also receive a notification that all pending write records have been processed (block 740). Thus, this notification may indicate that all write records from all computing devices have been processed rather than just the ones invoked by the processor(s). In response to receiving this notification of all write records being processed, the processor(s) change the status in the metadata back to stable (block 742). After changing the status to stable, the processor(s) may proceed with incrementing the reference count, performing the read of the newly merged data, and decrementing the reference count.

FIG. 8 is a flow diagram of a computer-readable medium 800, that store instructions that when executed, causes processor(s), such as the processor(s) 102, 202, and 210, to read remote data in a memory server that has distributed written data using multiple local memories storing write records at different remote devices. As an example, the written data may be distributed among different local memories 106of different client devices 101. The instructions cause the processor(s) to receive an indication that it is to read remote data (block 802). For instance, an application running on the processor(s) is to use such remote data for a computation, a measurement, and/or other operation that is based at least in part on the remote data.

The instructions cause the processor(s) to then access metadata of the remote data (block 804). For instance, the processor(s) may remotely access (e.g., using RDMA) a register of the memory server storing the remote data. The metadata includes information about the remote data, such as whether the remote data is undergoing a merge of multiple writes (e.g., using the status field 302), whether the remote data is undergoing a read (e.g., using the ref_cnt field 310), whether the remote data has pending writes that are currently not being merged (e.g., using the dirty field 304, the log_head_node field 306, and/or the log_head_off field 308).

The processor(s) check this information to determine how to proceed with the read. For instance, the instructions cause the processor(s) to check this information to determine whether the status is stable for the remote data (block 806). If the status is not stable (808) due to an ongoing merge of one or more write records into the remote data, the instructions cause the processor(s) to wait until the status stabilizes (block 810). For instance, the processor(s) may subscribe to notifications about the remote data and wait until receiving a notification from the memory server that the merge of the remote data has been completed. Alternatively, the processor(s) may wait a pre-determined period of time and/or may poll the memory server to acquire an updated status of the remote data at a later time.

If the processor(s) find that the remote data is stable (812), the instructions cause the processor(s) may determine whether the remote data is dirty (block 814). The processor(s) may determine this information by evaluating a corresponding flag in a corresponding portion (e.g., dirty field 304) of the metadata to determine whether the remote data is dirty.

If the remote data is not dirty (816) without any pending reads or writes, the instructions cause the processor(s) to increment a reference count (818). The reference count (e.g., the ref_cnt field 310) is a count of ongoing reads. Once the reference count has been incremented, the instructions cause the processor(s) to read the data from remote data (block 820). For instance, the processor(s) may use a remote access mechanism (e.g., RDMA) to read the remote data from the memory server. After completing the read, the instructions cause the processor(s) to decrement the reference count (block 822). In other words, the processor(s) may increment the reference count when a read is to happen or is happening and decrements the reference count after the read has been completed.

If the remote data is dirty (824), the instructions may cause the processor(s) to determine whether the reference count matches a pre-defined value (block 825). For example, the pre-defined value may be any value greater than zero indicating that there is at least one outstanding read operation. The processor(s) may determine this information by evaluating a corresponding portion (e.g., ref_cnt field 310) of the metadata to determine whether any connected devices are remotely reading the remote data. For instance, if a reference count matches the value (e.g., greater than 0), there is at least one ongoing read occurring. If there is at least one ongoing or pending read (826) of the remote data, the instructions cause the processor(s) to wait until the read(s) are completed (block 828). For instance, the processor(s) may subscribe to notifications about the remote data and wait until receiving a notification from the memory server that the read(s) of the remote data has been completed. Alternatively, the processor(s) may wait a pre-determined period of time and/or may poll the memory server to acquire an updated status of the read(s) of the remote data at a later time.

After the reads are completed (block 828) and/or upon determining that the reference count does not match a pre-determined value indicating an outstanding read (830), the instructions cause the processor(s) to cause the write records to be merged together. In anticipation of such a merge, the instructions cause the processor(s) to initiate the read changes the status in the metadata to an update-in-progress state rather than a stable state (block 832). In other words, the read invokes a merge that renders the data unstable until the merge is completed. The processor(s) may mark this remote data as unstable in anticipation of the merge.

After changing the status of the remote data to unstable, the instructions cause the processor(s) to send a merge instruction to the memory server to merge the write records into the remote data (block 834). In some implementations, the merge instruction may be separate from the read request and/or may be included with or implied by the read request without a separate merge instruction. As is discussed below in reference to the memory server, the memory server merges the remote data with the write records in an oldest to most recent order to make sure that all updates are processed in order received.

As part of the merge and/or after merging the write records, the processor(s) (and any other devices with a write record) receive a notification that write records have been merged to the remote data (block 836). The notification indicates that the write record is no longer pending and has been merged with the remote data. Accordingly, in response to the notification, the instructions cause the processor(s) to flush the corresponding locally stored write record (block 838). For instance, the processor(s) may delete any locally stored write record upon notification that such write records have been processed. For example, the deletion may include formatting the region or freeing up the allocation for the write record.

Since the processor(s) initiated the merge, the processor(s) may also receive a notification that all pending write records have been processed (block 840). Thus, this notification may indicate that all write records from all computing devices have been processed rather than just the ones invoked by the processor(s). This notification may be asynchronous between the memory server and the respective computing device(s). In response to receiving this notification of all write records being processed, the instructions may cause the processor(s) to change the status in the metadata back to stable (block 842). After changing the status to stable, the processor(s) may proceed with incrementing the reference count, performing the read of the newly merged data, and decrementing the reference count.

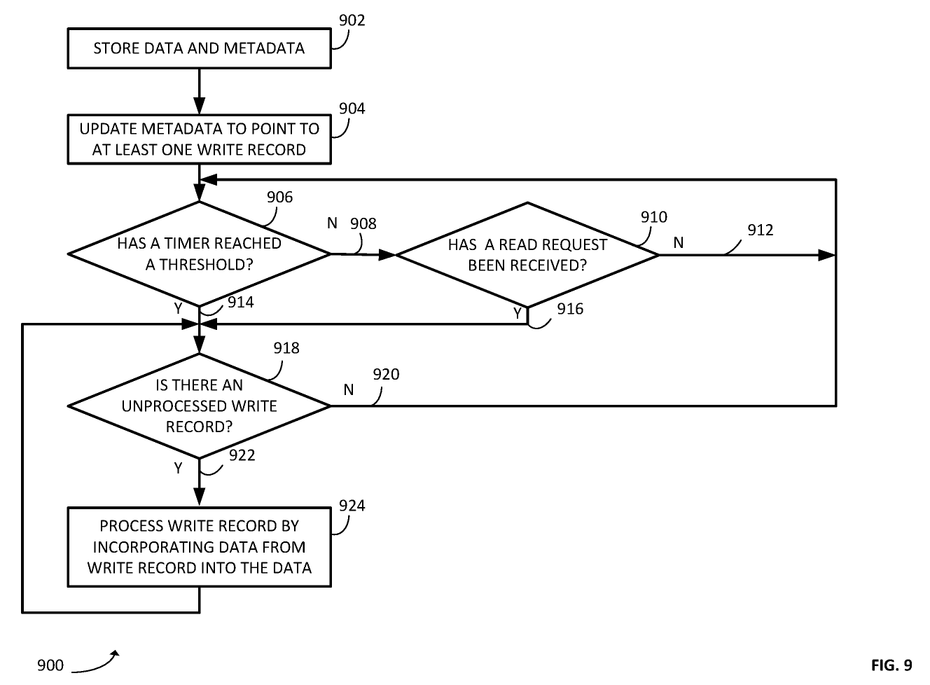

FIG. 9 is a flow chart of a process 900 that may be implemented by a memory server, such as the memory server 112and/or 206, to merge remote write records with local data. The local data is stored on the memory server and remote from the write records that are stored by client devices making write changes to the local data. The memory server, such as its processor(s), stores the data and metadata locally (block 902). For instance, the data may be stored with metadata as headers that indicate whether the data is stable (e.g., using status field 302), whether the data is dirty (e.g., using dirty field 304), point to a location of a most recent write record to change the data, and a count of a number of outstanding/ongoing read operations on the data.

The memory server receives a change to update the metadata to point to at least one write record (block 904). The write record may be located in a client device that sends the update of the metadata to the memory server. By updating the metadata to point to the at least one write record, the metadata logs a most recent change without having to track all of the changes locally potentially consuming a relatively large amount of the memory server’s resources for such logging. Furthermore, the metadata may be sequentially reprogrammed to point to different write records with each write record pointing to a next older write record meaning that the full chain from the most recent outstanding write is tracked through each change up to an oldest pending write that has yet to be merged with the local data.

During operation, the memory server determines whether a timer has lapsed since a last merge of records and/or since a last determination that there were no pending writes (block 906). This timer may indicate how frequently distributed write records are to be merged with the local data. The timer may be supplemented and/or replaced by a counter that counts a number of events before causing the pending write records to be merged. For instance, the counter may count a number of cycles similar to a timer and/or may count the number of write records.

If the counter or timer has not reached a threshold that corresponds to how frequently write records, defined as a number of clock cycles and/or in terms of read or write events, are to be merged (908), the memory server may check whether a read request has been received from a client device (block 910). For instance, the memory server may log received read requests that are purged once the reads are completed. If such a log is empty, a read request has been received. Otherwise, the memory server may determine that no read request has been received. If no read request has been received (912), the memory server may continue checking whether the timer has reached the threshold and/or whether a read request has been received.

Once the timer has reached a threshold (914) or a read request has been received (916), the memory server checks whether there is an unprocessed write record in at least one client device for the local data (block 918). The memory server may check whether there is an unprocessed write record by evaluating whether a pointer (e.g., log_head_node 306 and/or a log_head_off field 308) points to a valid location. If the pointer stores a pre-defined value (e.g., null, 0, etc.) that corresponds to no pending write records, the memory server may determine that there are no unprocessed write records (920). In response to such a determination, the memory server may restart the timer/counter and/or check for read requests for a next occasion to check for pending memory writes.

The memory server may assume that any stored non-null value or any value that matches an expected location format in the metadata indicates that there is at least one pending write (922). If there are any unprocessed write records corresponding to a pending write, the memory server may process a write record by incorporating data from the write record into the local data (block 924). The first write record processed by the memory server may be the oldest write record in a linked list. Specifically, the memory server may use the metadata to find a most recent write record using a pointer (e.g., log_head_node field 306 and/or a log_head_off field 308). The most recent write record may point to a previous write record using a pointer (e.g., prev_rcd_node field 408). Each write record may thus be linked to another previous write record if such a previous write record exists. Once the memory server reaches a write record that has a pointer (e.g., prev_rcd_node field 408) with a pre-defined value (e.g., null, 0, etc.) indicating that there is no previous write record, the memory server knows that this write record is the oldest pending write record. The memory server then processes this write record by adding the data from the write record to the local data.

Processing the write record may include the memory server setting a stability flag (e.g., the status field 302) to unstable until done processing the write records. Additionally or alternatively, this flag may be set by a client device request a read or generally instructing the memory server to merge the write records.

The memory server then processes each write record from oldest to most recent until all write records have been processed. Processing each write record may include notifying the client devices that store the write record that the write record has been processed to notify the client device that the write record may be purged. Furthermore, when the last write record of a batch of pending write records has been processed, processing the last write record may include notifying a client device that instructed (or sent a read request) to the memory server to invoke the merge.

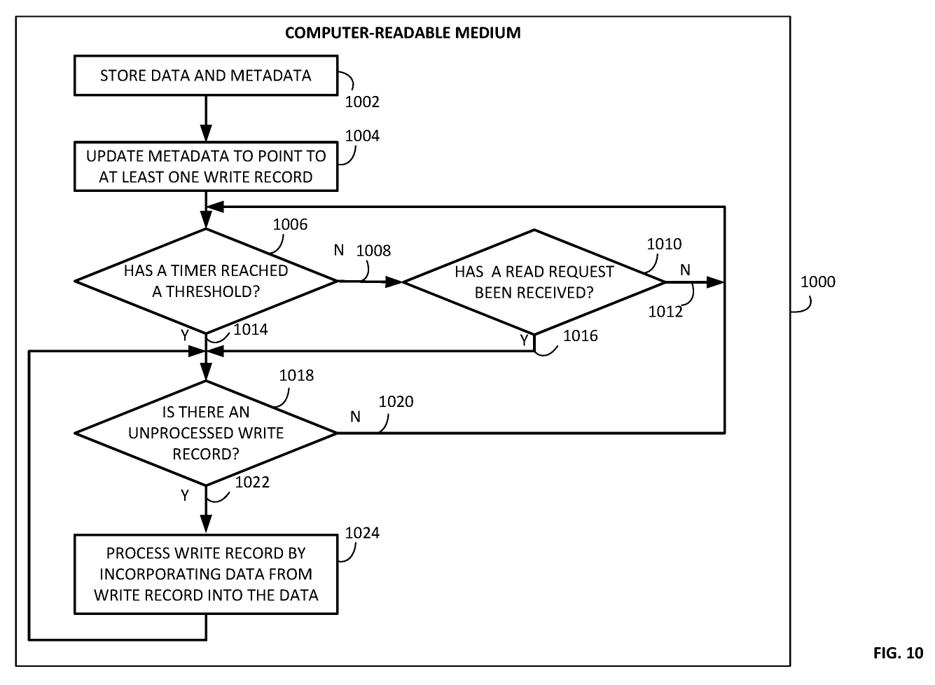

FIG. 10 is a flow diagram of a computer-readable medium 1000 that includes instructions, that when executed by processor(s) of a memory server, such as the memory server 112and/or 206, merges remote write records with local data. The processor(s) may be similar to the processor(s) 102, 202, and/or 210. The local data is stored on the memory server and remote from the write records that are stored by client devices making write changes to the local data. The instructions cause the memory server and its processor(s) to store the data and metadata locally (block 1002). For instance, the data may be stored with metadata as headers that indicate whether the data is stable (e.g., using status field 302), whether the data is dirty (e.g., using dirty field 304), point to a location of a most recent write record to change the data, and a count of a number of outstanding/ongoing read operations on the data.

The memory server receives a change to update the metadata to point to at least one write record (block 1004). The write record may be located in a client device that sends the update of the metadata to the memory server. By updating the metadata to point to the at least one write record, the metadata logs a most recent change without having to track all of the changes locally potentially consuming a relatively large amount of the memory server’s resources for such logging. Furthermore, the metadata may be sequentially reprogrammed to point to different write records with each write record pointing to a next older write record meaning that the full chain from the most recent outstanding write is tracked through each change up to an oldest pending write that has yet to be merged with the local data.

During operation, the instructions cause the memory server and its processor(s) to determine whether a timer has lapsed since a last merge of records and/or since a last determination that there were no pending writes (block 1006). This timer may indicate how frequently distributed write records are to be merged with the local data. The timer may be supplemented and/or replaced by a counter that counts a number of events before causing the pending write records to be merged. For instance, the counter may count a number of cycles similar to a timer and/or may count the number of write records.

If the counter or timer has not reached a threshold (1008), the instructions cause the memory server and its processor(s) to check whether a read request has been received from a client device (block 1010). For instance, the memory server may log received read requests that are purged once the reads are completed. If such a log is empty, a read request has been received. Otherwise, the instructions cause the memory server and its processor(s) to determine that no read request has been received. If no read request has been received (1012), the instructions cause the memory server and its processor(s) to continue checking whether the timer has reached the threshold and/or whether a read request has been received.

Once the timer has reached a threshold (1014) or a read request has been received (1016), the instructions cause the memory server and its processor(s) to check whether there is an unprocessed write record in at least one client device for the local data (block 1018). Based on the instructions, the memory server and its processor(s) check whether there is an unprocessed write record by evaluating whether a pointer (e.g., log_head_node 306 and/or a log_head_off field 308) points to a valid location. If the pointer stores a pre-defined value (e.g., null, 0, etc.) that corresponds to no pending write records, the instructions cause the memory server and its processor(s) to determine that there are no unprocessed write records (1020). In response to such a determination, the instructions cause the memory server and its processor(s) to restart the timer/counter and/or check for read requests for a next occasion to check for pending memory writes.

The instructions may cause the memory server and its processor(s) to assume that any stored non-null value or any value that matches an expected location format in the metadata indicates that there is at least one pending write (1022). If there are any unprocessed write records corresponding to a pending write, the instructions cause the memory server and its processor(s) to process a write record by incorporating data from the write record into the local data (block 1024). The first write record processed by the memory server may be the oldest write record in a linked list. Specifically, the memory server may use the metadata to find a most recent write record using a pointer (e.g., log_head_node field 306 and/or a log_head_off field 308). The most recent write record may point to a previous write record using a pointer (e.g., prev_rcd_node field 408). Each write record may thus be linked to another previous write record if such a previous write record exists. Once the memory server reaches a write record that has a pointer (e.g., prev_rcd_node field 408) with a pre-defined value (e.g., null, 0, etc.) indicating that there is no previous write record, the memory server knows that this write record is the oldest pending write record. The memory server then processes this write record by adding the data from the write record to the local data.

Processing the write record may include the memory server setting a stability flag (e.g., the status field 302) to unstable until done processing the write records. Additionally or alternatively, this flag may be set by a client device request a read or generally instructing the memory server to merge the write records.

The memory server then processes each write record from oldest to most recent until all write records have been processed. Processing each write record may include notifying the client devices that store the write record that the write record has been processed to notify the client device that the write record may be purged. Furthermore, when the last write record of a batch of pending write records has been processed, processing the last write record may include notifying a client device that instructed (or sent a read request) to the memory server to invoke the merge.

One or more specific aspects of the present disclosure are described above. In an effort to provide a concise description of these aspects, all features of an actual implementation may not be described in the specification. It should be appreciated that in the development of any such actual implementation, as in any engineering or design project, numerous implementation-specific decisions are made to achieve the developers’ specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various aspects of the present disclosure, the articles “a,” “an,” “the,” and “said” are intended to mean that there are one or more of the elements. The terms “comprising,” “including,” and “having” are intended to be inclusive and mean that there may be additional elements other than the listed elements.

While certain features of the present disclosure have been illustrated and described herein, many modifications and changes will occur to those skilled in the art. It is, therefore, to be understood that the appended claims are intended to cover all such modifications and changes as fall within the true spirit of the present disclosure.

1. An electronic device, comprising:
local memory storing instructions; and
one or more processors configured to execute the instructions to cause the one or more processors to:
prepare to update remote data stored in a memory server that is exposed to the one or more processors for remote memory access, wherein preparing to update the remote data comprises;
allocating a region of the local memory to update the remote data;
in response to the allocation, storing a write record to the region, wherein the write record stores:
update data in a data field to update the remote data; and
a location in one or more location fields, wherein the location denotes where the update data of the write record is to be written; and
in response to storing the write record, flagging the remote data as having a pending update at the location by updating metadata of the remote data.

2. The electronic device of claim 1, wherein the write record is configured to:
track whether another node has a pending write of additional update data to the remote data after the electronic device has updated the metadata by updating a previous received node field of the write record; and
store an address in the remote data where the additional update is to be written by updating a previous received offset field of the write record.

3. The electronic device of claim 2, wherein preparing to update the remote data comprises storing a predetermined value in the previous received node field when the write record is a most recent write to the remote data.

4. The electronic device of claim 1, wherein preparing to update the remote data comprises storing a size of the update data in a size field.

5. The electronic device of claim 1, wherein the location comprises:
a source offset of the update data in a source offset field; or
a destination offset of the update data in a destination offset field.

6. The electronic device of claim 1, wherein instructions are configured to cause the one or more processors to generate the update data to be stored in the remote data.

7. The electronic device of claim 1, wherein updating the metadata of the remote data comprises:
marking the remote data with a pending write by setting a dirty bit of the metadata;
linking to the write record by writing a node identifier of the write record to a log node field of the metadata; and
linking to the write record by writing a local offset for the write record in the local memory to an offset field of the metadata.

8. The electronic device of claim 1, comprising a network interface card, wherein allocating the region comprises exposing the region to remote access through the network interface card.

9. The electronic device of claim 8, wherein exposing the region comprises exposing the region to remote direct memory access (RDMA) through the network interface card.

10. A method for managing memory access, comprising:
checking, by a client processor, a status field of metadata corresponding to remote data in a memory server as part of a read operation;
in response to the status field indicating that the remote data is available for reading, discovering, by the client processor, that a pending write exists from another client for the remote data by checking a dirty bit of the metadata;
in response to the pending write existing, checking, by the client processor, a reference count of the metadata ;
in response to the reference count matching one of one or more values, changing, by the client processor, the status field of the metadata indicating that an update is in progress;
in response to changing the status field, sending a merge instruction from the client processor to the memory server;
receiving, at the client processor, a response that write records are merged with the pending write; and
marking, by the client processor, the status of the remote data as stable by updating the status field of the metadata.

11. The method of claim 10, comprising:
receiving a release notification from the memory server; and
in response to receiving the release notification, flushing a local write record from local memory.

12. The method of claim 10, comprising:
in response to changing the status of the remote data to stable, increasing the reference count;
in response to increasing the reference count, initiating a read of the remote data; and
in response to completing the read, decrementing the reference count.

13. The method of claim 10, wherein accessing the metadata comprises accessing the metadata using remote direct memory access (RDMA).

14. The method of claim 10, comprising:
storing, in a log head node field of the metadata, a node address for a log head node that is a head of a linked list of write records with pending changes to the remote data;
storing, in a log head offset field of the metadata, a remote offset of the update data in the remote data; and
storing the reference count in a reference count field of the metadata.

15. The method of claim 14, comprising:
storing a source offset in a source offset field of the write record;
storing a destination offset in a destination offset field of the write record;
storing a size of the update data in a size field of the write record;
storing an address of a next write record in a previous received node field of the write record;
storing an offset of the next write record in a previous received offset field of the write record; and
storing the update data in a data field of the write record.

16. A method for remote access comprising:
allocating, by a client processor, a region of local memory to update remote data in a memory server, wherein the local memory is within a computing system that includes the client processor;
in response to the allocation, storing, by the client processor, a write record to the region, wherein the write record stores:
the update data in a data field; and
a location in one or more location fields, wherein the location denotes where the update data of the write record is to be written; and
in response to storing the write record, flagging the remote data as having a pending update at the location by updating metadata of the remote data to point to the write record.

17. The method of claim 16, comprising:
flagging a status of the remote data as currently being merged by storing a corresponding value to a status field of the write record;
storing an address of a next write record in a previous received node field of the write record storing an offset of the next write record in a previous received offset field of the write record; and
storing a size of the update data in a size field of the write record.

18. The method of claim 16, wherein the location comprises:
a source offset of the update data in a source offset field; or
a destination offset of the update data in a destination offset field.

19. The method of claim 16, wherein updating the metadata of the remote data comprises:
marking the remote data with a pending write by setting a dirty bit of the metadata;
linking to the write record by writing a node identifier of the write record to a log node field of the metadata; and
linking to the write record by writing a local offset for the write record in the local memory to an offset field of the metadata.

20. The method of claim 16, comprising:
checking, by the client processor, a status field of the metadata;
in response to the status field of the metadata indicating that the remote data is available for reading, discovering, by the client processor, a pending write exists from another client for the remote data by checking a dirty bit of the metadata; in response to pending write existing, checking, by the client processor, a reference count of the metadata;
in response to the reference count matching one or more values, changing, by the client processor, the status field of the metadata indicating that an update is in progress;
in response to changing the status field, sending a merge instruction from the client processor to the memory server;
receiving, at the client processor, a response that the records are merged with the pending write; and
marking, by the client processor, the status of the remote data as stable by updating the status field of the metadata.
